(19) United States
(12) Patent Application Publication
(10) Pub. No.: US 2013/0330920 A1
(43) Pub. Date: Dec. 12, 2013

(54) METHOD AND APPARATUS FOR SUBSTRATE PRECLEAN WITH HYDROGEN CONTAINING HIGH FREQUENCY RF PLASMA

(71) Applicants: Guojun Liu, San Jose, CA (US); Xianmin Tang, San Jose, CA (US); Anantha Subramani, San Jose, CA (US); Wei W. Wang, Santa Clara, CA (US)

(72) Inventors: Guojun Liu, San Jose, CA (US); Xianmin Tang, San Jose, CA (US); Anantha Subramani, San Jose, CA (US); Wei W. Wang, Santa Clara, CA (US)

(73) Assignee: Applied Materials, Inc., Santa Clara, CA (US)

(21) Appl. No.: 13/490,059

(22) Filed: Jun. 6, 2012

(51) Int. Cl. H01L 21/283

(52) U.S. Cl. 438/608; 257/E21.159

(57) ABSTRACT

A high-frequency, hydrogen-based radio-frequency (RF) plasma is used to reduce a metal oxide and other contaminant disposed in an aperture that is formed in an ultra-low k dielectric material. Because the frequency of the plasma is at least about 40 MHz and the primary gas in the plasma is hydrogen, metal oxide can be advantageously removed without damaging the dielectric material.

### BACKGROUND OF THE INVENTION

1. Field of the Invention

Embodiments of the present invention relate generally to semiconductor substrate processing and, more particularly, to systems and methods for cleaning a metal oxide and residue from a surface of a substrate.

2. Description of the Related Art

In the microfabrication of integrated circuits and other devices, electrical interconnect features, such as contacts, vias, and lines, are commonly constructed on a substrate using high aspect ratio apertures formed in a dielectric material. The presence of native oxides and other contaminants such as etch residue within these small apertures is highly undesirable, contributing to void formation during subsequent metalization of the aperture and increasing the electrical resistance of the interconnect feature. Known techniques for removing residue and metal oxides form a surface prior to metalization are generally plasma etch processes, in which ions from a plasma are used to bombard the surface.

As microelectronic devices are continually scaled down in size and transistors are more closely spaced in such devices, dielectric materials having a dielectric constant lower than that of silicon dioxide, i.e., less than 3.9, are necessary to reduce parasitic capacitance in said devices, thereby enabling faster switching speeds and reduced heat generation. These so-called “low-k” materials can withstand the ion bombardment of conventional plasma preclean processes, which are generally performed prior to metalization. Therefore, most low-k materials can generally be cleaned using such processes without suffering significant damage. However, materials having an ultra-low dielectric constant, i.e., materials having a dielectric constant value of approximately 2.5 or less, are typically porous and much more susceptible to damage from ion bombardment. Because of this, conventional ion etch processes are unable to clean residue from apertures formed in ultra-low k materials without significantly damaging these dielectric materials.

Accordingly, there is a need in the art for systems and methods for cleaning features formed in an ultra low-k material without damaging the ultra low-k material.

### SUMMARY OF THE INVENTION

One or more embodiments of the present invention provide systems and methods for cleaning metal oxide and residue from an aperture formed in an ultra-low k dielectric material without damaging the dielectric material. A high-frequency, hydrogen-based radio-frequency (RF) plasma is used to reduce the metal oxide in the aperture, where the frequency of the plasma is at least about 40 MHz. The high frequency of the RF plasma has two primary benefits. First, the high-frequency RF plasma provides a concentration of hydrogen radicals that can reduce copper oxide in the aperture at a relatively high rate. Second, the high-frequency of the RF plasma lowers the plasma ion energy, since each ion has very short acceleration time and therefore accrues less kinetic energy than ions in a lower frequency RF plasma. With lower ion energy, delicate low-k dielectric materials can be exposed to such a plasma without sustaining significant damage.

In another embodiment, a method of processing a substrate disposed in a processing chamber is provided that includes introducing a hydrogen (H₂) containing gas mixture into the processing chamber, coupling power at a frequency of at least about 40 MHz to the hydrogen (H₂) containing gas mixture to form a plasma, and removing an oxide from the substrate in the presence of the plasma.

In another embodiment, a method of processing a substrate disposed in a processing chamber is provided that includes positioning the substrate in a process region of the processing chamber, wherein the substrate has an aperture formed in a low k dielectric material deposited on the substrate and a metal oxide formed on a surface of the aperture, and exposing the metal oxide to a plasma formed in the process region, the plasma being formed by introducing a hydrogen (H₂) containing gas mixture into the processing chamber and capacitively coupling plasma source power into the process region, wherein the plasma source power comprises very high frequency (VHF) power having a frequency of at least about 40 MHz.

In still another embodiment, a method of processing a substrate disposed in a processing chamber is provided that includes positioning the substrate in a process region of a first chamber of the multi-chamber processing system. after the step of positioning the substrate in the process region of the first chamber, introducing a hydrogen (H₂) containing gas mixture into the first chamber and capacitively coupling plasma source power into the process region of the first chamber, wherein the plasma source power comprises very high frequency (VHF) power having a frequency of at least about 40 MHz, after the step of introducing the hydrogen-containing gas mixture and capacitively coupling plasma source power, transferring the substrate under vacuum from the first chamber to the second chamber, and after the step of transferring the substrate, depositing a metal film in the aperture.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIGS. 1A-1C are schematic cross-sectional views of an aperture that is formed in a low-k dielectric material and which may benefit from embodiments of the invention.

FIG. 2 is a schematic cross-section of a plasma processing chamber, configured according to an embodiment of the invention.

FIG. 3 is a flowchart of method steps for processing a substrate in a processing chamber, according to one embodiment of the present invention.

FIG. 4 is a bar chart illustrating the efficacy of different embodiments of the invention.

FIG. 5 is a bar chart further illustrating the efficacy of different embodiments of the invention.

FIG. 6 is a schematic plan view diagram of an exemplary multi-chamber processing system configured to perform a high-frequency, hydrogen-based plasma process on substrates, according to one or more embodiments of the invention.

FIG. 7 is a flowchart of method steps for processing a substrate in a multi-chamber processing system, according to one or more embodiments of the present invention.

For clarity, identical reference numbers have been used, where applicable, to designate identical elements that are common between figures. It is contemplated that features of one embodiment may be incorporated in other embodiments without further recitation.

### DETAILED DESCRIPTION

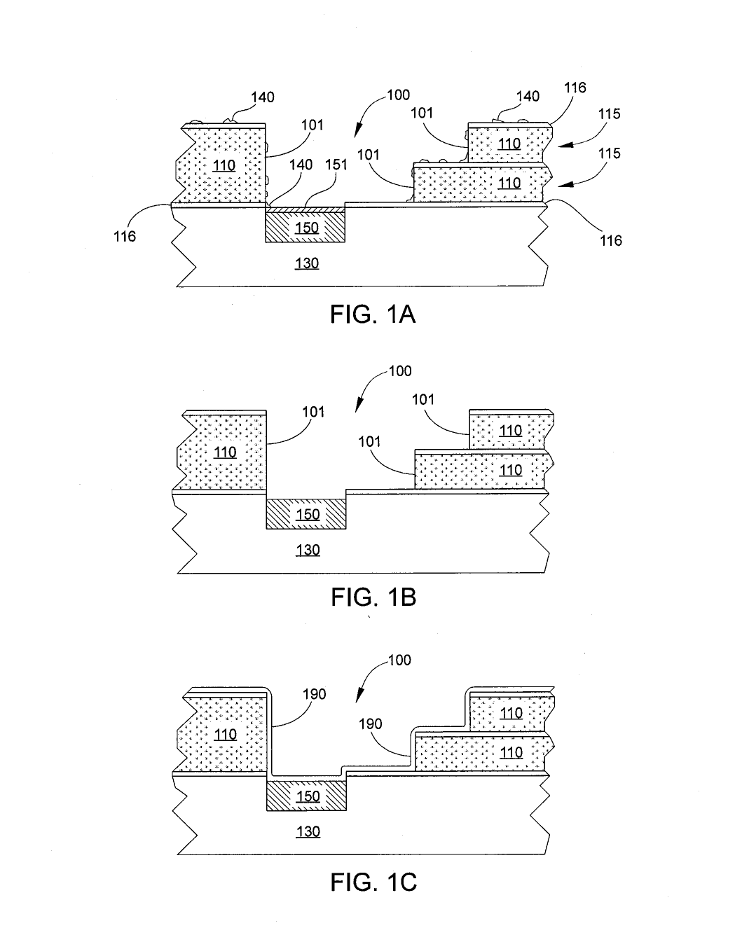

FIGS. 1A-1C are schematic cross-sectional views of an aperture 100 that is formed in a low-k dielectric material 110 and which may benefit from embodiments of the invention. Low-k dielectric material 110 is deposited on a substrate 130 and, in the embodiment illustrated in FIGS. 1A-1C, is deposited in one or more layers 115. Low-k dielectric material 110 includes a dielectric material that has a dielectric constant (k-value) significantly less than that of silicon dioxide (SiO₂), which is 3.9. In some embodiments, low-k dielectric material 110 includes an ultra low-k dielectric, having a k-value equal to or less than 2.5. To achieve such low k-values, low-k dielectric material 110 is commonly a porous material, since voids can have a dielectric constant of nearly 1. Therefore, the dielectric constant of a porous material may be reduced by increasing the porosity of the material, for example with nano-scale air pockets trapped in a carbon-silicon matrix. Due to the high porosity typical of ultra low-k materials, such materials are generally susceptible to ion damage when exposed to plasma.

Layers 115 of low-k dielectric material 110 may be separated by etch stop layers 116. Etch stop layers 116 may include silicon carbide (SiC), SiOC, silicon nitride (Si₃N₄), and the like, and may be single- or bi-layer structures. In the course of fabricating a microelectronic device on a substrate 130, aperture 100 is formed in one or more layers 115 of dielectric material 110 and through one or more etch stop layers 116. Substrate 130 may be a silicon (Si), germanium (Ge), gallium arsenide (GaAs), or other substrate known in the art on which a low-k dielectric material may be deposited. Aperture 100 is generally used to form an electrically conductive interconnect via or trench as part of a microelectronic device on substrate 130, and consequently is etched through low-k dielectric material 110 to expose an underlying metal structure 150. Typically, underlying metal structure 150 is comprised of copper or a copper alloy, but other metals also fall within the scope of the invention.

Because the plasma ashing process used to remove photoresist from substrate 130 is generally performed in a different processing system than the metalization process used to fill aperture 100, substrate 130 typically experiences an “air break” prior to the afore-mentioned metalization process when the substrate is transferred from the vacuum environment of one system to atmosphere, transported to the second system, then transferred to the vacuum environment of the second system. Consequently, underlying metal structure 150 includes a metal oxide layer 151, as shown in FIG. 1A. The thickness of metal oxide layer 151 varies depending on the metals included in underlying metal structure 150, the duration of the air break between plasma ashing and metalization, etc. In any case, the presence of metal oxide layer 151 adds unwanted electrical resistance to the interconnect structure formed in aperture 100, contributes to void formation during metalization of aperture 100, and discourages adhesion of subsequent metalization layers, and is therefore undesirable.

As shown in FIG. 1A, aperture 100 may also have contamination 140 present on various surfaces prior to the metalization of aperture 100. Contamination 140 may include etch residue that has not been completely removed, residual photo-resist, and other contaminants. Contamination 140 can contribute to void formation and adhesion issues for subsequently deposited layers, which is particularly undesirable when aperture 100 has a high aspect ratio (depth vs. thickness) and uniform deposition on sidewalls 101 is important.

One or more embodiments of the present invention provide systems and methods for cleaning the metal oxide layer 151 and contamination 140 from aperture 100 without damaging low-k dielectric material 110. A high-frequency, hydrogen (H₂) based radio-frequency (RF) plasma is used to reduce the metal oxide of the metal oxide layer 151, where the frequency of the plasma is at least about 40 MHz. At frequencies of 40 MHz and higher, the acceleration time of ions in the plasma is shortened significantly with respect to lower frequency RF plasmas. Coupled with the fact that hydrogen ions have very little mass, ions in such a plasma do not develop enough kinetic energy to damage fragile ultra low-k materials, such as low-k dielectric material 110. FIG. 1B illustrates aperture 100 after undergoing such a high-frequency hydrogen-bases process. FIG. 1C illustrates aperture 100 after a subsequent metalization process has conformally deposited a metal layer 190 on aperture 100. Metal layer 190 may be a diffusion barrier layer, a seed layer for subsequent copper plating, and the like.

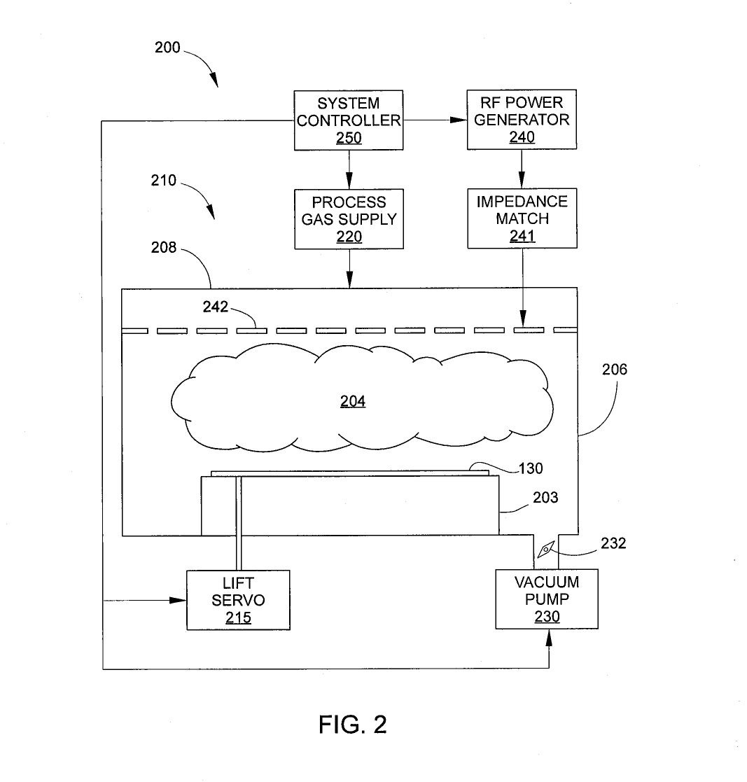

FIG. 2 is a schematic cross-section of a plasma processing chamber 200, configured according to an embodiment of the invention. Plasma processing chamber 200 includes a chamber body 210, a process gas supply 220, a vacuum pump 230, a high-frequency RF power generator 240, and a system controller 250.

Chamber body 210 has sidewalls 206 and a ceiling 208, and includes a substrate support 203 and a processing region 204 disposed within. Substrate support 203 may include any technically feasible apparatus for supporting a substrate during processing by plasma processing chamber 200, such as the substrate 130 described with reference to FIGS. 1A-1C. In some embodiments, substrate support 203 includes one or more heating elements for heating the substrate 130 during processing. In some embodiments, substrate support 203 is raised and lowered by a lift servo 215. In embodiments in which plasma processing chamber 200 is a capacitively coupled plasma processing chamber, substrate support 203 may be configured as one of the two electrodes disposed on opposite sides of processing region 204.

Process gas supply 220 provides hydrogen (H₂) and optionally other process gases to processing region 204 defined inside the chamber body 210. Vacuum pump 230 evacuates the chamber body 210 prior to processing and removes process gas from chamber body 210 during processing through a valve 232. Valve 232 may be operated to facilitate regulation of the evacuation rate of gases from chamber body 210. The evacuation rate through the valve 232 and the incoming gas flow rate from process gas supply 220 determine pressure and process gas residency time within the processing region 204 of the chamber body 210.

High-frequency RF power generator 240 is an RF power generator configured to drive plasma generation in chamber body 210 at a frequency of at least about 40 MHz. High-frequency RF power generator 240 provides high frequency power through an optional impedance match element 241 to an electrode 242 disposed adjacent the processing region 204. In the embodiment illustrated in FIG. 2, electrode 242 is configured as a process gas distribution element, such as a showerhead or an array of gas injection nozzles, through which hydrogen and optional other process gases are introduced into processing region 204. In some embodiments, process gas may be introduced into processing region 204 via inlets and/or nozzles in addition to or in lieu of a showerhead. Electrode 242 is oriented substantially parallel to the surface of substrate 130 and capacitively couples plasma source power into processing region 204. Thus, processing region 204 is disposed between substrate 130 and electrode 242. In some embodiments, substrate support 203 is electrically grounded and in other embodiments, substrate support 203 is also electrically coupled to high-frequency RF power generator 240, so that plasma source power is capacitively coupled to processing region 204 from two sides.

System controller 250 is configured to control the operation of plasma processing chamber 200, including output power level of high-frequency RF power generator 240, flow rate of the various process gases directed to processing region 204 by process gas supply 220, adjustment of valve 232, etc.

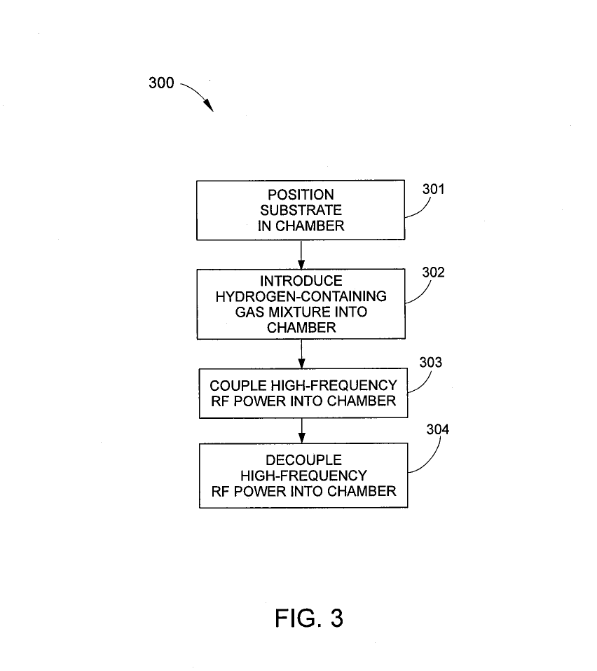

FIG. 3 is a flowchart of method steps for processing a substrate in a processing chamber, according to one embodiment of the present invention. Method 300 facilitates the removal of metal oxide layers and other contaminants from one or more apertures formed in an ultra-low k dielectric material without damaging the dielectric material. Although the method steps are described in conjunction with plasma processing chamber 200 in of FIG. 2, persons skilled in the art will understand that any processing chamber configured to perform the method steps falls within the scope of the invention.

As shown, method 300 begins at step 301, in which substrate 130 is positioned on substrate support 203. Substrate 130 includes aperture 100, metal oxide layer 151 on an underlying metal structure 150, and contamination 140 on various surfaces, as illustrated in FIG. 1A.

At step 302, a hydrogen-containing gas mixture is introduced into processing region 204 of chamber body 210. Valve 232 is positioned and the flow rate of the process gases is adjusted so as to control the pressure in chamber body 210 to a desired process pressure. As noted above, the hydrogen-containing gas mixture may be introduced to processing region 204 through electrode 242, which may be configured as a process gas distribution element, such as a showerhead, for more uniform distribution.

In some embodiments, the hydrogen-containing gas consists essentially of hydrogen gas (H₂). A plasma formed from the hydrogen-containing gas is effective to reduce metal oxides, particularly copper oxides (CuOₓ). In some embodiments, the hydrogen-containing gas includes an inert gas to assist in the removal of contamination 140 through more intensive ion bombardment of the surfaces of aperture 100. Examples of suitable inert gases that may be used in step 302 include argon (Ar) and helium (He). In such embodiments, the concentration of the inert gas does not exceed 30 atomic percent of the hydrogen-containing gas mixture, to prevent ion damage of low-k dielectric material 110. In some embodiments, the concentration of inert gas does not exceed 10 atomic percent of the hydrogen-containing gas, such as when low-k dielectric material 110 is more easily damaged by ion bombardment. In still other embodiments, the concentration of inert gas does not exceed 5 atomic percent of the hydrogen-containing gas, such as when low-k dielectric material 110 comprises materials that are very easily damaged by ion bombardment, such as Black Diamond III™. The optimal concentration of inert gas is determined in such embodiments by the integration flow of plasma etching and ashing steps that have been performed on substrate 130 prior to method 300 and metal deposition that will be performed on substrate 130 after method 300.

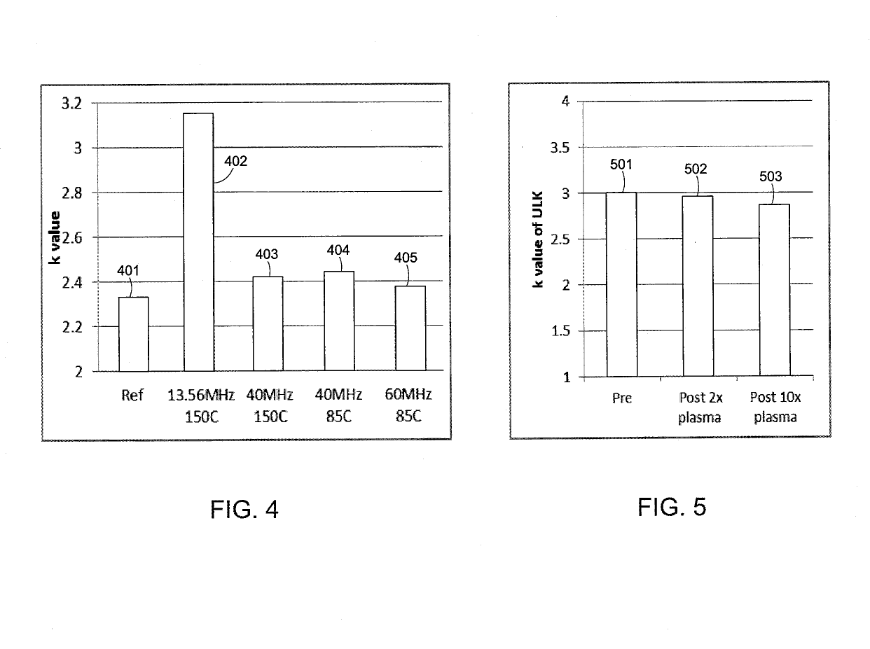

In step 303, plasma source power is coupled into processing region 204 from high-frequency RF power generator 240 to produce an RF plasma in processing region 204, where the RF plasma source power has a frequency of at least about 40 MHz. In this way, the various surfaces of aperture 100, and thus contamination 140 and metal oxide layer 151, are exposed to the RF plasma formed from the processing gas (i.e., hydrogen-containing gas and optional other gases) in processing region 204. Hydrogen radicals from the hydrogen-based RF plasma in processing region 204 reduce the metal oxide, thereby exposing the underlying metal structure 150. Due to the high frequency of the RF plasma and the low atomic mass of the hydrogen radical generated in the plasma, low-k dielectric material 110 may be exposed to the plasma without suffering significant ion damage, as illustrated below in FIGS. 4 and 5. In some embodiments, substrate 130 is heated during step 303 to facilitate removal of metal oxide layer 151 and/or contamination 140. In such embodiments, substrate 130 may be heated to a temperature of 25° C. to 200° C.

In embodiments in which one or more inert gases are included in the hydrogen-containing gas, contamination 140 can also be removed by the plasma in processing region 204. Because the concentration of the inert gas or gases in the hydrogen-containing gas is no greater than 30 atomic percent, damage to low-k dielectric material 110 can be avoided. In some embodiments, the concentration of the inert gas or gases in the hydrogen-containing gas is less than 10 atomic percent or 5 atomic percent, depending on the ability of low-k dielectric material 110 to withstand ionic bombardment by these more massive ions. One of skill in the art, upon reading this disclosure, can readily determine a suitable concentration of inert gases when the removal of contamination 140 is desired.

In step 304, after metal oxide layer 151 has been substantially removed and underlying metal structure 150 is exposed, plasma source power from high-frequency RF power generator 240 is decoupled from processing region 204. After step 304, aperture 100 is free of contamination 140 and metal oxide layer 151 has been removed, as illustrated in FIG. 1B.

It is noted that method 300 is described in terms of a capacitively coupled plasma processing chamber by way of example only, and other configurations of plasma processing chamber may also use a high-frequency, hydrogen-based plasma to remove a metal oxide without exceeding the scope of the invention. For example, an inductively coupled plasma processing chamber, or a plasma processing chamber using a combination of inductively coupled and capacitively coupled plasma may also be used to implement embodiments of the invention.

FIG. 4 is a bar chart illustrating the efficacy of different embodiments of the invention. Specifically, the effect of different embodiments on the k-value of a low-k dielectric material, such as low-k dielectric material 110, is contrasted with the effect of a conventional RF plasma on the same low-k dielectric material. The reference sample 401 indicates that the low-k dielectric material in question has a k-value of about 2.35 prior to plasma treatment. Sample 402 indicates that after a conventional treatment, i.e., a hydrogen-based plasma treatment with RF plasma having a frequency of 13.56 MHz and a substrate temperature of 150° C., the low-k dielectric material has a k-value of almost 3.2. This large change in k-value indicates significant ion damage. Samples 403-405 indicate that after hydrogen-based plasma treatments with RF plasma having a frequency of at least 40 MHz and different substrate temperatures, the k-value of the low-k dielectric material shows very little change. Thus, the high-frequency plasma can be used without damaging delicate low-k dielectric materials.

FIG. 5 is a bar chart further illustrating the efficacy of different embodiments of the invention. Specifically, treatment with a 40 MHz, hydrogen-based plasma is demonstrated to have little effect on the k-value of a low-k dielectric material, such as low-k dielectric material 110. Column 501 is a baseline measurement indicating that the low-k dielectric material in question has a k-value of about 3.0 prior to plasma treatment. Column 502 indicates that after two hydrogen-based plasma treatments with RF plasma having a frequency of 40 MHz, the k-value slightly decreases. Column 503 indicates that even after ten hydrogen-based plasma treatments with RF plasma having a frequency of 40 MHz, the k-value only slightly decreases, which is attributed to the fact that the original surface was treated by ashing plasma prior to the hydrogen-based plasma treatment. Thus, such a high-frequency plasma can be used without damaging delicate low-k dielectric materials.

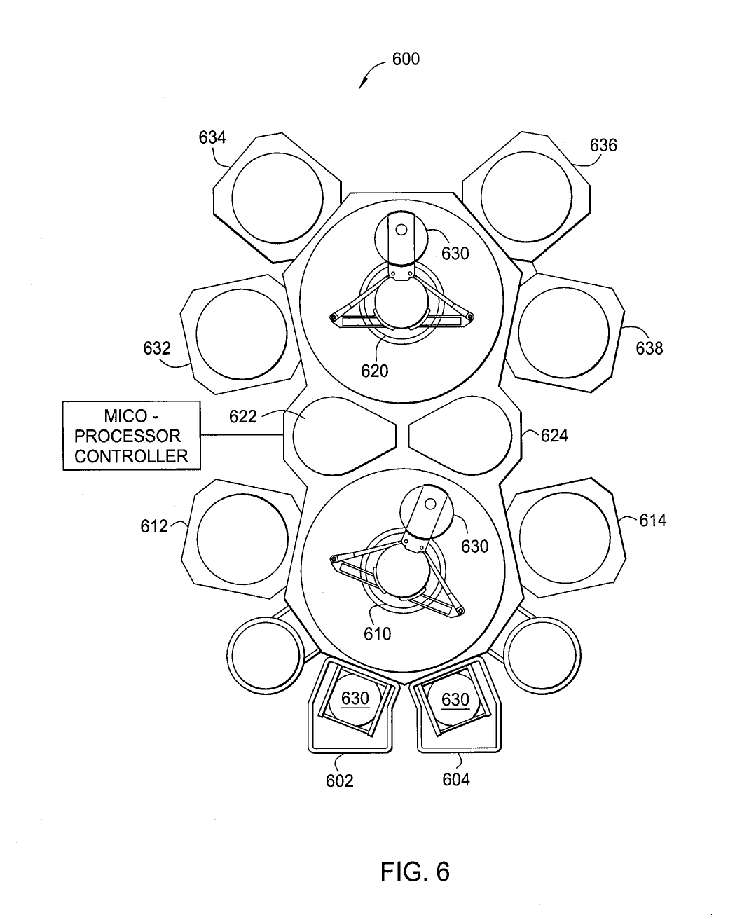

FIG. 6 is a schematic plan view diagram of an exemplary multi-chamber processing system 600 configured to perform a high-frequency, hydrogen-based plasma process on substrates 630, according to one or more embodiments of the invention. The substrates 630 may be configured as described with reference to substrates 130 discussed above. The multi-chamber processing system 600 includes one or more load lock chambers 602, 604 for transferring substrates 630 into and out of the vacuum portion of multi-chamber processing system 600. Consequently, load lock chambers 602, 604 can be pumped down to introduce substrates into multi-chamber processing system 600 for processing under vacuum. A first robot 610 transfers substrates 630 between load lock chambers 602 and 604, transfer chambers 622 and 624, and a first set of one or more processing chambers 612 and 614. A second robot 620 transfers substrates 630 between transfer chambers 622 and 624 and processing chambers 632, 634, 636, 638.

One or both of processing chambers 612 and 614 are configured to perform a hydrogen-based, high-frequency plasma process according to embodiments of the invention described herein. The transfer chambers 622, 624 can be used to maintain ultrahigh vacuum conditions while substrates are transferred within multi-chamber processing system 600. Processing chambers 632, 634, 636, 638 are configured to perform various substrate-processing operations including cyclical layer deposition (CLD), atomic layer deposition (ALD), chemical vapor deposition (CVD), physical vapor deposition (PVD), and the like.

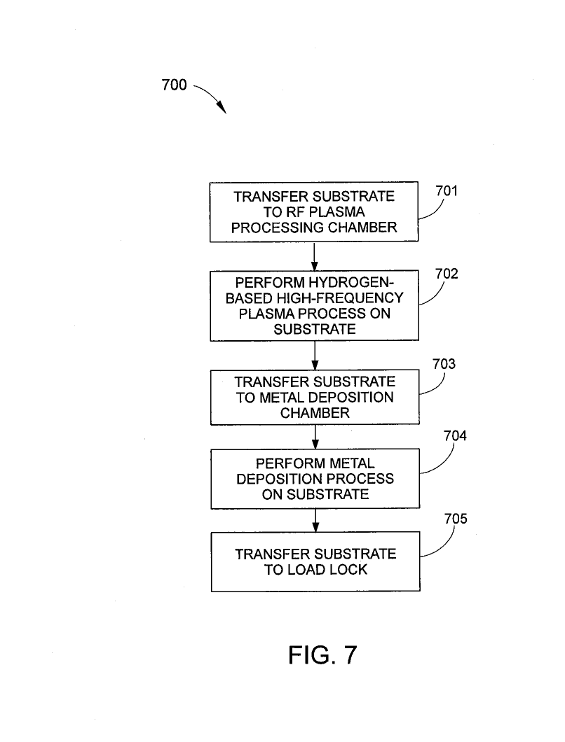

FIG. 7 is a flowchart depicting a method 700 for processing a substrate in a multi-chamber processing system, according to one or more embodiments of the present invention. Method 700 enables the removal of metal oxide layers and other contaminants from one or more apertures formed in an ultra-low k dielectric material on the substrate without damaging the dielectric material. Furthermore, method 700 enables the deposition of barrier layers, seed layers, and/or other metalization layers in said apertures immediately after the removal of the metal oxide layer and prior to any exposure of the apertures to atmospheric conditions. Consequently, the one or more metal deposition processes are performed on oxide-free metal surfaces. Although the method steps are described in conjunction with multi-chamber processing system in FIG. 7, such as the multi-chamber processing system 600 described in reference to FIG. 6, persons skilled in the art will understand that any multi-chamber processing system configured to perform the method steps is within the scope of the invention.

As shown, method 700 begins at step 701, in which a substrate 630 is transferred from one of load lock chambers 602, 604 to one of processing chambers 612 and 614.

In step 702, substrate 630 undergoes a high-frequency, hydrogen-based plasma process as described above in conjunction with FIG. 3. The plasma process removes metal oxide layers and contamination from apertures formed in a low-k dielectric material without damaging the low-k dielectric material.

In step 703, substrate 630 is transferred by first robot 610 and second robot 620 to one or more of processing chambers 632, 634, 636, or 638.

In step 704, substrate 630 undergoes one or more metal deposition processes, such as a barrier layer deposition, a seed layer deposition, etc. Because substrate 630 has not been exposed to atmosphere since the high-frequency, hydrogen-based plasma process of step 702, the metal deposition processes of step 704 are performed on extremely clean surfaces.

In step 705, substrate 630 is transferred back to one of load lock chambers 602 or 604.

In sum, a high-frequency, hydrogen-based radio-frequency (RF) plasma is used in some embodiments to reduce metal oxide in the aperture and remove other contaminants from various surfaces of the aperture. Because the frequency of the plasma is at least about 40 MHz and the primary gas in the plasma is hydrogen, metal oxide can be advantageously removed without damaging the dielectric material.

While the foregoing is directed to embodiments of the present invention, other and further embodiments of the invention may be devised without departing from the basic scope thereof, and the scope thereof is determined by the claims that follow.

We claim:

1. A method of processing a substrate disposed in a processing chamber, the method comprising:
introducing a hydrogen (H₂) containing gas mixture into the processing chamber;
coupling power at a frequency of at least about 40 MHz to the hydrogen (H₂) containing gas mixture to form a plasma; and
removing an oxide from the substrate in the presence of the plasma.

2. The method of claim 1, wherein the hydrogen (H₂) containing gas mixture comprises at least about 70 atomic percent hydrogen (H₂).

3. The method of claim 1, wherein the hydrogen (H₂) containing gas mixture comprises at least about 90 atomic percent hydrogen (H₂).

4. The method of claim 1, wherein the hydrogen (H₂) containing gas mixture comprises an inert gas.

5. The method of claim 1, further comprising, after introducing the hydrogen (H₂) containing gas mixture, introducing a second hydrogen (H₂) containing gas mixture into the processing chamber, wherein the second hydrogen-containing gas mixture comprises a higher atomic percent of hydrogen (H₂) than the hydrogen (H₂) containing gas mixture first introduced into the processing chamber.

6. The method of claim 1, wherein coupling power comprises capacitively coupling power to the hydrogen (H₂) containing gas mixture.

7. The method of claim 6, wherein capacitively coupling power into the hydrogen (H₂) containing gas mixture comprises capacitively coupling plasma source power to the hydrogen (H₂) containing gas mixture via an impedance match element.

8. The method of claim 1, wherein introducing the hydrogen (H₂) containing gas mixture into the processing chamber comprises flowing the hydrogen-containing gas through a gas-distribution element disposed above the substrate.

9. The method of claim 8, wherein the power is coupled to the hydrogen (H₂) containing gas mixture via the gas-distribution element.

10. The method of claim 1, wherein removing the oxide comprises removing a metal oxide disposed on the substrate to expose a substantially oxide-free metal.

11. The method of claim 10, wherein the metal oxide comprises copper oxide (CuOₓ).

12. A method of processing a substrate disposed in a processing chamber, the method comprising:
positioning the substrate in a process region of the processing chamber, wherein the substrate has an aperture formed in a low k dielectric material deposited on the substrate and a metal oxide formed on a surface of the aperture; and
exposing the metal oxide to a plasma formed in the process region, the plasma being formed by introducing a hydrogen (H₂) containing gas mixture into the processing chamber and capacitively coupling plasma source power into the process region,
wherein the plasma source power comprises very high frequency (VHF) power having a frequency of at least about 40 MHz.

13. The method of claim 12, wherein the metal oxide comprises copper oxide (CuOₓ).

14. The method of claim 12, wherein the hydrogen-containing gas mixture comprises at least about 70 atomic percent hydrogen (H₂).

15. The method of claim 12, wherein capacitively coupling the plasma source power into the process region comprises capacitively coupling plasma source power into the process region from a surface of the processing chamber that is substantially parallel to a surface of the substrate facing the process region.

16. A method of processing a substrate in a multi-chamber processing system, the method comprising the steps of:
positioning the substrate in a process region of a first chamber of the multi-chamber processing system;
after the step of positioning the substrate in the process region of the first chamber, introducing a hydrogen (H₂) containing gas mixture into the first chamber and capacitively coupling plasma source power into the process region of the first chamber, wherein the plasma source power comprises very high frequency (VHF) power having a frequency of at least about 40 MHz;
after the step of introducing the hydrogen-containing gas mixture and capacitively coupling plasma source power, transferring the substrate under vacuum from the first chamber to the second chamber; and
after the step of transferring the substrate, depositing a metal film in the aperture.

17. The method of claim 16, wherein the metal oxide comprises copper oxide (CuOₓ).

18. The method of claim 16, wherein the hydrogen (H₂) containing gas mixture comprises at least about 90 atomic percent hydrogen (H₂).

19. The method of claim 16, wherein the hydrogen (H₂) containing gas mixture comprises an inert gas.

20. The method of claim 19, wherein the concentration of the inert gas does not exceed 30 atomic percent of the hydrogen-containing gas.
